(19) United States
(12) Patent Application Publication
(10) Pub. No.: US 2017/0275508 A1
(43) Pub. Date: Sep. 28, 2017

(54) RESIN COMPOSITION AND ADHESIVE FILM AND CIRCUIT BOARD MADE OF THE SAME

(71) Applicants: FuKui Precision Component (Shenzhen) Co., Ltd., Shenzhen (CN); HongQiSheng Precision Electronics (QinHuangDao) Co., Ltd., Qinhuangdao (CN); Zhen Ding Technology Co., Ltd., Tayuan (TW)

(72) Inventors: MAO-FENG HSU, New Taipei (TW); CHEN-FENG YEN, New Taipei (TW); YEN-CHIN HSIAO, New Taipei (TW)

(21) Appl. No.: 15/191,516

(22) Filed: Jun. 23, 2016

(30) Foreign Application Priority Data
Mar. 25, 2016 (CN) 201610176599.3

(51) Int. Cl. C09J 133/00; C09J 11/08; C09J 7/02; H05K 1/03; B32B 7/12; B32B 27/42; B32B 27/38; C09J 9/00; C08L 33/00

(52) U.S. Cl. CPC C09J 133/00; C09J 9/00; C09J 11/08; C09J 7/02; C08L 33/00; B32B 7/12; B32B 27/42; B32B 27/38; H05K 1/0353; C09J 2433/00; C09J 2203/326; C09J 2205/102; C08L 2205/02; C08L 2205/03; C08L 2207/53; C08L 2203/20; B32B 2457/08; H05K 2201/0195

(57) ABSTRACT

A resin composition suitable as an adhesive layer and as a circuit board substrate includes an acrylic resin, a non-photosensitive resin with carboxyl groups, nano core-shell particles, a photoinitiator, and a solvent, such adhesive layer and circuit board substrate being high-strength and temperature-resistant whilst retaining flexibility. The acrylic resin is in an amount by weight of 150 parts in the resin composition, the non-photosensitive resin is in an amount by weight of 30 parts to 80 parts in the resin composition, the nano core-shell particles are in an amount by weight of 5 parts to 30 parts in the resin composition, and the photoinitiator is in an amount by weight of 1 part to 10 parts in the resin composition.

### FIELD

The subject matter herein generally relates to a resin composition, and an adhesive film and a circuit board made of the resin composition.

### BACKGROUND

Flexible circuit boards usually include adhesive films made of a photosensitive resin composition. Typically, an adhesive film is made by mixing an acrylic resin, an epoxy resin, and a photoinitiator to cause the mixture to undergo a reaction, and solidifying the mixture after the reaction. The adhesive film made of the resin composition is typically brittle, thus flexible rubber particles are usually added to the resin composition to improve flexibility of the adhesive film. However, the flexible rubber particles usually have a great molecular weight and are not compatible with the acrylic resin, thus affecting the improvement of the flexibility of the adhesive film.

### BRIEF DESCRIPTION OF THE DRAWINGS

Implementations of the present technology will now be described, by way of example only, with reference to the attached figures.

FIG. 1 is a diagrammatic view of an embodiment of an adhesive film made of a resin composition according to the present disclosure.

FIG. 2 is a diagrammatic view of an embodiment of a circuit board made of the resin composition according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

An embodiment of a resin composition comprises an acrylic resin, a non-photosensitive resin with carboxyl groups, nano core-shell particles, a photoinitiator, and a solvent. The acrylic resin, the non-photosensitive resin with carboxyl groups, the nano core-shell particles, and the photoinitiator are dispersed in the solvent. The acrylic resin is in an amount by weight of about 150 parts in the resin composition. The non-photosensitive resin is in an amount by weight of about 30 parts to about 80 parts in the resin composition. The nano core-shell particles are in an amount by weight of about 5 parts to about 30 parts in the resin composition. The photoinitiator is in an amount by weight of about 1 part to about 10 parts in the resin composition. The amount of the solvent can be varied to ensure that a viscosity of the resin composition is greater than 1000 cps.

An acrylic resin according to the above formulation can be obtained from Taiwan Yukuan Corporation under the trade name “SMR-200”.

The non-photosensitive resin with carboxyl groups is a resin having carboxyl groups and no carbon-carbon double bonds, and does not undergo a chemical reaction under ultraviolent radiation. In at least one embodiment, the non-photosensitive resin with carboxyl groups is polymethylmethacrylate (PMMA) obtainable from Evonik Industry under the trade name “1035N”.

Each nano core-shell particle comprises a core and a shell wrapped around the core. The core can be made of a material selected from a group consisting of butadiene, styrene, polybutadiene, siloxanes, acrylic resin, or any combination thereof. The shell can be made of a thermosetting resin. The nano particle has a diameter less than or equal to 100 nm. The nano core-shell particle can be obtained from Kanaka Corporation under the trade name “MX-257”.

The photoinitiator can be selected from a group consisting of α-hydroxy ketone, acylphosphine oxide, α-amino ketone, ester compound, or any combination thereof. In at least one embodiment, the α-hydroxy ketone is selected from a group consisting of 2-hydroxyl-2-methyl-1-phenyl-1-acethone, 1-hydroxy cyclohexyl phenyl ketone, benzil dimethyl ketal, diphenyl ketone, isopropylthioxanthone, or any combination thereof. The acylphosphine oxide is selected from a group consisting of diphenyl (2,4,6-trimethylbenzoyl) phosphine oxide, phenyl di(2,4,6-trimethylbenzoyl) phosphine oxide, or any combination thereof. The α-amino ketone is selected from a group consisting of 2-methyl-1-(4-methylthiophenyl)-2-morpholino-1-acetone, 2-benzyl-2-dimethylamino-1-(4-morpholino phenyl)-1-butanone, carbazole oxime ester, or any combination thereof.

In at least one embodiment, the solvent is butanone. In other embodiments, the solvent can be other organic solvent capable of dissolving resin. For example, the solvent can be an ether compound, an alcohol compound, or a ketone compound.

In at least one embodiment, the resin composition further comprises at least one of polyisocyanate, an epoxy resin, and a melamine resin. When the resin composition comprises polyisocyanate, the polyisocyanate is in an amount by weight of about 10 parts to about 40 parts in the resin composition. When the resin composition comprises epoxy resin, the epoxy resin is in an amount by weight of about 10 parts to about 40 parts in the resin composition. When the resin composition comprises melamine resin, the melamine resin is in an amount by weight of about 5 parts to about 20 parts in the resin composition. The epoxy resin can be obtained from Dow Chemical Company under the trade name “DER-331”. At least one of the polyisocyanate, epoxy resin, and melamine resin can undergo a polymerization reaction to form a cross-linking network structure when heated, thereby increasing a cross-linking density of the resin composition.

In at least one embodiment, the resin composition further comprises a coloring agent. The coloring agent is in an amount by weight of about 1 part to about 5 parts in the resin composition. The coloring agent can be selected from a group consisting of a pigment, an organic dye, or any combination thereof. The pigment can be selected from a group consisting of an inorganic pigment, an organic pigment, or any combination thereof. The inorganic pigment can be metal pigment. The organic dye can be selected from a group consisting of natural organic dye, synthesized organic dye, or any combination thereof. In at least one embodiment, the organic dye can be a phthalocyanine compound, an azoic compound, a diazo compound, an azine compound, a three-methane compound, or a condensed polycyclic compound. The azoic compound can be selected from a group consisting of Permanent Orange RN (C.I. Pigment Orange 5), Bronze Red (C.I. Pigment Red 21), benzidine yellow G (C.I. Pigment Yellow 12), or any combination thereof.

The resin composition can be prepared by following steps. The acrylic resin is in an amount by weight of about 150 parts the non-photosensitive resin with carboxyl groups in an amount by weight of about 30 parts to about 80 parts, the nano core-shell particles are in an amount by weight of about 5 parts to about 30 parts, the photoinitiator is in an amount by weight of about 1 part to about 10 parts, and the coloring agent is in an amount by weight of about 1 part to about 5 parts, all components being added to a container. The solvent in a proper amount is then added to the container to form a mixture. Stirring of the mixture causes the acrylic resin, the non-photosensitive resin with carboxyl groups, the nano core-shell particles, the photoinitiator, and the coloring agent to be dispersed in the solvent, thereby forming the resin composition.

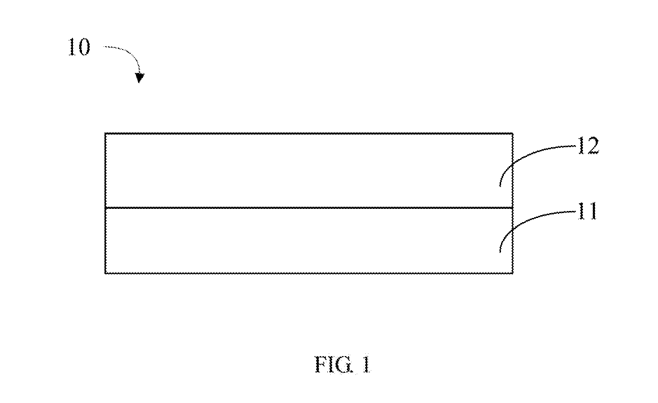

FIG. 1 illustrates an adhesive film 10 made of the resin composition. The adhesive film 10 comprises a release film 11 and at least one adhesive layer 12, each being attached to a surface of the release film 11. It is well-known that a release film is widely used as a protective film for a variety of adhesive coatings, and is laminated on a surface of the adhesive coating and serves as a protective film. Each adhesive layer 12 is formed by coating the resin composition onto the surface of the release film 11 and drying the resin composition under ultraviolent radiation or by curing. The adhesive layer 12 can comprise desired patterns formed by exposure and development.

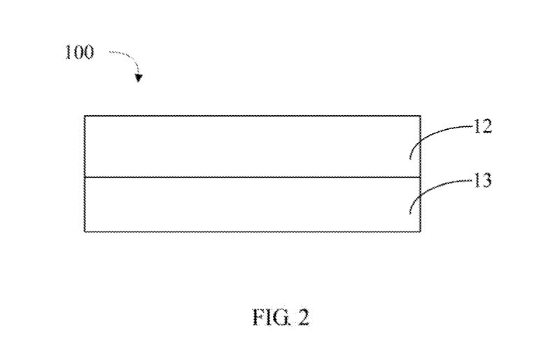

FIG. 2 illustrates a circuit board 100 comprising at least one substrate 13 and at least one adhesive layer 12, each being attached to one surface of each substrate 13. Each adhesive layer 12 is attached to the substrate 13 by heat pressing, and comprises desired patterns formed by exposure and development. The circuit board 100 may be a rigid-flexible circuit board, an IC carrier, and a High Density Interconnector (HDI) circuit board.

The cores of the nano core-shell particles improve the flexibility of the adhesive layer 12 made of the resin composition. The shells of the nano core-shell particles link the nano core-shell particles to the acrylic resin, thereby preventing the cores of the nano core-shell particles from aggregating together and enhancing the flexibility of the adhesive layer 12. Since the shells of the nano core-shell particles are made of thermosetting resin which usually comprises carboxylic acid groups, a developing solution used in the process of exposure and development can remove the adhesive layer 12 in the developed area by fully reacting with the carboxylic acid groups. Thus, the adhesive layer 12 after the process of exposure and development has no remaining adhesive in the developed area. The non-photosensitive resin with carboxyl groups can facilitate the process of exposure and development and decrease a shrinkage of the resin composition during drying. Since the resin composition further comprises at least one of polyisocyanate, epoxy resin, and melamine resin which undergoes a polymerization reaction to form a cross-linking network structure when heated, the cross-linking density of the resin composition is increased. The increase in cross-linking density causes the resin composition to be resistant to alkalis and high temperatures. An improved thermal resistance is a characteristic of the circuit board 100 made of the resin composition.

### EXAMPLE

Acrylic resin (Manufacturer: Taiwan Yukuan Corporation, trade name: SMR-200) of 150 g, non-photosensitive resin with carboxyl groups (Manufacturer: Evonik Industry, trade name: 1035N) of 50 g, nano core-shell particles (Manufacturer: Kanaka Corporation, trade name: MX-257) of 10 g, 2-hydroxyl-2-methyl-1-phenyl-1-acethone of 6 g, and Permanent Orange RN of 1.5 g, epoxy resin (Manufacturer: Dow Chemical Company, trade name: DER-331) of 17 g, and butanone of 75 g was added to a container of 1000 ml to form a mixture. The mixture was stirred to form the resin composition.

### COMPARATIVE EXAMPLE 1

Acrylic resin (Manufacturer: Yukuan Corporation, trade name: SMR-200) of 150 g, non-photosensitive resin with carboxyl groups (Manufacturer: Evonik Industry, trade name: 1035N) of 50 g, rubber particles (Manufacturer: JSR Corporation, trade name: XER-32C) of 10 g, 2-hydroxyl-2-methyl-1-phenyl-1-acethone of 6 g, and Permanent Orange RN of 1.5 g, epoxy resin (Manufacturer: Dow Chemical Company, trade name: DER-331) of 17 g, and butanone of 75 g was added to a container of 1000 ml to form a mixture. The mixture was stirred to form a composition.

### COMPARATIVE EXAMPLE 2

Acrylic resin (Manufacturer: Yukuan Corporation, trade name: SMR-200) of 150 g, non-photosensitive resin with carboxyl groups (Manufacturer: Evonik Industry, trade name: 1035N) of 50 g, 2-hydroxyl-2-methyl-1-phenyl-1-acethone of 6 g, and Permanent Orange RN of 1.5 g, epoxy resin (Manufacturer: Dow Chemical Company, trade name: DER-331) of 17 g, and butanone of 75 g was added to a container of 1000 ml to form a mixture. The mixture is stirred to form a composition.

Three adhesive layers were made of the resin composition of the above example and the compositions of the above comparative examples 1 and 2. A copper foil was provided as a substrate of a circuit board and was attached to the surface of each of the three adhesive layers. The three adhesive layers were subjected to exposure and development, thereby forming three flexible circuit boards. Whether the adhesive layers of the three circuit boards had remaining adhesive in the developed area after the process of exposure and development were observed. Then, the flexibility, the thermal resistance, and the adhesive strength of the adhesive layers were tested, and the test results shown in Table 1. The flexibility was tested by bending a circuit board through 180 degrees and calculating the number of times that the circuit board remained non-fractured after being bent. The thermal resistance was tested by exposing the circuit board to a temperature equal to or greater than 288 degree.C. for 30 seconds and then cooling, and repeating the step another two times. After the thermal resistance test, if the solder did not peel off or drop out from the through hole of the circuit board, the result of the thermal resistance test is pass, otherwise, the result is fail.

TABLE 1

| | product | | |
|---|---|---|---|
| | | comparative | comparative |
| property | example | example 1 | example 2 |
| does the product have remaining | yes | no | no |
| adhesive in the developed area | | | |
| after exposure and development? | | | |
| adhesive strength under ASTM | 5B | 4B | 3B |
| standard | | | |
| the number of times that the | 17 | 8 | 0 |
| circuit board doesn't fracture after | | | |
| being bent | | | |
| thermal resistance | pass | pass | fail |

Table 1 illustrates that the adhesive layer made of the resin composition of the above example has no remaining adhesive in the developed area after the process of exposure and development. Furthermore, the adhesive layer made of the resin composition of the above example has a greater flexibility, a greater thermal resistance, and a greater adhesive strength than the adhesive layer made of the compositions of the above comparative examples 1 and 2.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A resin composition comprising:
an acrylic resin;
a non-photosensitive resin with carboxyl groups;
nano core-shell particles;
a photoinitiator; and
a solvent;
wherein the acrylic resin is in an amount by weight of about 150 parts in the resin composition, the non-photosensitive resin is in an amount by weight of about 30 parts to about 80 parts in the resin composition, the nano core-shell particles are in an amount by weight of about 5 parts to about 30 parts in the resin composition, and the photoinitiator is in an amount by weight of about 1 part to about 10 parts in the resin composition.

2. The resin composition of claim 1, wherein each nano core-shell particle comprises a core and a shell wrapped around the core; the core is made of a material selected from a group consisting of butadiene, styrene, polybutadiene, siloxanes, acrylic resin, or any combination thereof; the shell is made of a thermosetting resin.

3. The resin composition of claim 1, wherein each nano particle has a diameter less than or equal to 100 nm.

4. The resin composition of claim 1, wherein the non-photosensitive resin with carboxyl groups is polymethylmethacrylate.

5. The resin composition of claim 1, wherein the photoinitiator is selected from a group consisting of α-hydroxy ketone, acylphosphine oxide, α-amino ketone, ester compound, or any combination thereof.

6. The resin composition of claim 5, wherein the α-hydroxy ketone is selected from a group consisting of 2-hydroxyl-2-methyl-1-phenyl-1-acethone, 1-hydroxy cyclohexyl phenyl ketone, benzil dimethyl ketal, diphenyl ketone, isopropylthioxanthone, or any combination thereof; the acylphosphine oxide is selected from a group consisting of diphenyl (2,4,6-trimethylbenzoyl) phosphine oxide, phenyl di(2,4,6-trimethylbenzoyl) phosphine oxide, or any combination thereof; the α-amino ketone is selected from a group consisting of 2-methyl-1-(4-methylthiophenyl)-2-morpholino-1-acetone, 2-benzyl-2-dimethylamino-1-(4-morpholino phenyl)-1-butanone, carbazole oxime ester, or any combination thereof.

7. The resin composition of claim 1, wherein the solvent is an ether compound, an alcohol compound, or a ketone compound.

8. The resin composition of claim 7, wherein the solvent is butanone.

9. The resin composition of claim 1 further comprising at least one polyisocyanate, an epoxy resin, and a melamine resin, wherein when the resin composition comprises the polyisocyanate, the polyisocyanate is in an amount by weight of about 10 parts to about 40 parts in the resin composition; when the resin composition comprises the epoxy resin, the epoxy resin is in an amount by weight of about 10 parts to about 40 parts in the resin composition; when the resin composition comprises the melamine resin, the melamine resin is in an amount by weight of about 5 parts to about 20 parts in the resin composition.

10. The resin composition of claim 1 further comprising a coloring agent, wherein the coloring agent is in an amount by weight of about 1 part to about 5 parts in the resin composition.

11. The resin composition of claim 10, wherein the coloring agent is selected from a group consisting of a pigment, an organic dye, or any combination thereof.

12. The resin composition of claim 11, wherein the pigment is selected from a group consisting of an inorganic pigment, an organic pigment, or any combination thereof; the organic dye is selected from a group consisting of natural organic dye, synthesized organic dye, or any combination thereof.

13. An adhesive film comprising:
a release film; and
at least one adhesive layer each attached to a surface of the release film, and made of a resin composition;
wherein the resin composition comprises an acrylic resin, a non-photosensitive resin with carboxyl groups, nano core-shell particles, a photoinitiator, and a solvent;
wherein the acrylic resin is in an amount by weight of about 150 parts in the resin composition, the non-photosensitive resin is in an amount by weight of about 30 parts to about 80 parts in the resin composition, the nano core-shell particles are in an amount by weight of about 5 parts to about 30 parts in the resin composition, and the photoinitiator is in an amount by weight of about 1 part to about 10 parts in the resin composition.

14. The adhesive film of claim 13, wherein each nano core-shell particle comprises a core and a shell wrapped around the core; the core is made of a material selected from a group consisting of butadiene, styrene, polybutadiene, siloxanes, acrylic resin, or any combination thereof; the shell is made of a thermosetting resin.

15. The adhesive film of claim 13, wherein the non-photosensitive resin with carboxyl groups is polymethylmethacrylate.

16. The adhesive film of claim 13, wherein the photoinitiator is selected from a group consisting of α-hydroxy ketone, acylphosphine oxide, α-amino ketone, ester compound, or any combination thereof.

17. The adhesive film of claim 16, wherein the α-hydroxy ketone is selected from a group consisting of 2-hydroxyl-2-methyl-1-phenyl-1-acethone, 1-hydroxy cyclohexyl phenyl ketone, benzil dimethyl ketal, diphenyl ketone, isopropylthioxanthone, or any combination thereof; the acylphosphine oxide is selected from a group consisting of diphenyl (2,4,6-trimethylbenzoyl) phosphine oxide, phenyl di(2,4,6-trimethylbenzoyl) phosphine oxide, or any combination thereof; the α-amino ketone is selected from a group consisting of 2-methyl-1-(4-methylthiophenyl)-2-morpholino-1-acetone, 2-benzyl-2-dimethylamino-1-(4-morpholino phenyl)-1-butanone, carbazole oxime ester, or any combination thereof.

18. The adhesive film of claim 13, wherein the resin composition further comprises at least one polyisocyanate, an epoxy resin, and a melamine resin, when the resin composition comprises the polyisocyanate, the polyisocyanate is in an amount by weight of about 10 parts to about 40 parts in the resin composition; when the resin composition comprises the epoxy resin, the epoxy resin is in an amount by weight of about 10 parts to about 40 parts in the resin composition; when the resin composition comprises the melamine resin, the melamine resin is in an amount by weight of about 5 parts to about 20 parts in the resin composition.

19. The adhesive film of claim 13, wherein the resin composition further comprises a coloring agent; the coloring agent is in an amount by weight of about 1 part to about 5 parts in the resin composition.

20. A circuit board comprising:
at least one substrate; and
at least one adhesive layer each attached to one surface of each substrate and made of a resin composition;
wherein the resin composition comprises an acrylic resin, a non-photosensitive resin with carboxyl groups, nano core-shell particles, a photoinitiator, and a solvent;
wherein the acrylic resin is in an amount by weight of about 150 parts in the resin composition, the non-photosensitive resin is in an amount by weight of about 30 parts to about 80 parts in the resin composition, the nano core-shell particles are in an amount by weight of about 5 parts to about 30 parts in the resin composition, and the photoinitiator is in an amount by weight of about 1 part to about 10 parts in the resin composition.
